(19) United States
(12) Patent Application Publication
(10) Pub. No.: US 2022/0216375 A1
(43) Pub. Date: Jul. 7, 2022

(54) SEMICONDUCTOR LIGHT-EMITTING ELEMENT AND METHOD OF MANUFACTURING SEMICONDUCTOR LIGHT-EMITTING ELEMENT

(71) Applicant: NIKKISO CO., LTD., Tokyo (JP)

(72) Inventors: Noritaka NIWA, Hakusan-shi Ishikawa (JP); Tetsuhiko INAZU, Hakusan-shi Ishikawa (JP)

(21) Appl. No.: 17/506,305

(22) Filed: Oct. 20, 2021

(30) Foreign Application Priority Data
Jan. 7, 2021 (JP) 2021-001667

(51) Int. Cl. H01L 33/44; H01L 33/40

(52) U.S. Cl. CPC H01L 33/44; H01L 33/007; H01L 2933/0016; H01L 33/405

(57) ABSTRACT

A semiconductor light-emitting element includes a p-side pad opening provided on a p-side contact electrode and an n-side pad opening provided on an n-side contact electrode, covers side surfaces of an n-type semiconductor layer, an active layer, and a p-type semiconductor layer, covers the p-side contact electrode in a portion different from the p-side pad opening, and covers the n-side contact electrode in a portion different from the n-side pad opening. The protective layer includes a first dielectric layer made of SiO₂, a second dielectric layer made of an oxide material different from a material of the first dielectric layer and covering the first dielectric layer, and a third dielectric layer made of SiO₂ and covering the second dielectric layer. A carbon concentration of the first dielectric layer is smaller than a carbon concentration of the third dielectric layer.

### RELATED APPLICATION

Priority is claimed to Japanese Patent Application No. 2021-001667, filed on Jan. 7, 2021, the entire content of which is incorporated herein by reference.

### BACKGROUND OF THE INVENTION

### 1. Field of the Invention

The present invention relates to a semiconductor light-emitting element and a method of manufacturing a semiconductor light-emitting element.

### 2. Description of the Related Art

A semiconductor light-emitting element includes an n-type semiconductor layer, an active layer, and a p-type semiconductor layer stacked on a substrate. An n-side electrode is provided on the n-type semiconductor layer, and a p-side electrode is provided on the p-type semiconductor layer. A protective film made of silicon oxide is provided on the surface of the semiconductor light-emitting element (see, for example, JP2016-171141).

A protective film of silicon nitride is known as having a high moisture resistance, but silicon nitride has a property to absorb ultraviolet light and so could lead to lower light emission efficiency.

### SUMMARY OF THE INVENTION

The present invention address the above-described issue, and a purpose thereof is to provide a semiconductor light-emitting element in which both moisture resistance and light emission efficiency can be improved.

An embodiment of the present invention relates to a semiconductor light-emitting element including: an n-type semiconductor layer made of an n-type AlGaN-based semiconductor material; an active layer provided on a first upper surface of the n-type semiconductor layer and made of an AlGaN-based semiconductor material; a p-type semiconductor layer provided on the active layer; a p-side contact electrode provided on an upper surface of the p-type semiconductor layer and containing Rh; an n-side contact electrode provided on a second upper surface of the n-type semiconductor layer; a protective layer including a p-side pad opening provided on the p-side contact electrode and an n-side pad opening provided on the n-side contact electrode, the protective layer covering side surfaces of the n-type semiconductor layer, the active layer, and the p-type semiconductor layer, covering the p-side contact electrode in a portion different from the p-side pad opening, and covering the n-side contact electrode in a portion different from the n-side pad opening; a p-side pad electrode connected to the p-side contact electrode in the p-side pad opening; and and an n-side pad electrode connected to the n-side contact electrode in the n-side pad opening. The protective layer includes a first dielectric layer made of SiO₂, a second dielectric layer made of an oxide material different from a material of the first dielectric layer and covering the first dielectric layer, and a third dielectric layer made of SiO₂ and covering the second dielectric layer. A carbon concentration of the first dielectric layer is smaller than a carbon concentration of the third dielectric layer. Each of the first dielectric layer, the second dielectric layer, and the third dielectric layer has a transmittance for deep ultraviolet light emitted by the active layer of 80% or higher.

Another embodiment of the present invention relates to a method of manufacturing a semiconductor light-emitting element. The method includes: forming an active layer made of an AlGaN-based semiconductor material on a first upper surface of an n-type semiconductor layer made of an n-type AlGaN-based semiconductor material; forming a p-type semiconductor layer on the active layer; removing a portion of the p-type semiconductor layer and the active layer to expose a second upper surface of the n-type semiconductor layer; forming a p-side contact electrode containing Rh on an upper surface of the p-type semiconductor layer; forming an n-side contact electrode on a second upper surface of the n-type semiconductor layer; forming a first dielectric layer made of a first oxide material, covering side surfaces of the n-type semiconductor layer, the active layer, and the p-type semiconductor layer, and covering the p-side contact electrode and the n-side contact electrode; forming a second dielectric layer made of a second oxide material different from the first oxide material and covering the first dielectric layer, forming a third dielectric layer made of SiO₂ and covering the second dielectric layer by atomic layer deposition; forming a p-side pad opening by removing the first dielectric layer, the second dielectric layer, and the third dielectric layer on the p-side contact electrode; forming an n-side pad opening by removing the first dielectric layer, the second dielectric layer, and the third dielectric layer on the n-side contact electrode; forming a p-side pad electrode connected to the p-side contact electrode in the p-side pad opening; and forming an n-side pad electrode connected to the n-side contact electrode in the n-side pad opening. Each of the first dielectric layer, the second dielectric layer, and the third dielectric layer has a transmittance for deep ultraviolet light emitted by the active layer of 80% or higher.

### BRIEF DESCRIPTION OF THE DRAWINGS

FIG. 1 is a cross-sectional view schematically showing a configuration of a semiconductor light-emitting element according to the embodiment;

FIG. 2 schematically shows a step of manufacturing the semiconductor light-emitting element;

FIG. 3 schematically shows a step of manufacturing the semiconductor light-emitting element;

FIG. 4 schematically shows a step of manufacturing the semiconductor light-emitting element;

FIG. 5 schematically shows a step of manufacturing the semiconductor light-emitting element;

FIG. 6 schematically shows a step of manufacturing the semiconductor light-emitting element;

FIG. 7 schematically shows a step of manufacturing the semiconductor light-emitting element;

FIG. 8 schematically shows a step of manufacturing the semiconductor light-emitting element;

FIG. 9 schematically shows a step of manufacturing the semiconductor light-emitting element; and

FIG. 10 schematically shows a step of manufacturing the semiconductor light-emitting element.

### DETAILED DESCRIPTION OF THE INVENTION

The invention will now be described by reference to the preferred embodiments. This does not intend to limit the scope of the present invention, but to exemplify the invention.

A detailed description will be given of an embodiment of the present invention with reference to the drawings. The same numerals are used in the description to denote the same elements, and a duplicate description is omitted as appropriate. To facilitate the understanding, the relative dimensions of the constituting elements in the drawings do not necessarily mirror the relative dimensions in the light-emitting element.

The semiconductor light-emitting element according to the embodiment is configured to emit “deep ultraviolet light” having a central wavelength λ of about 360 nm or shorter and is a so-called deep ultraviolet-light-emitting diode (UV-LED) chip. To output deep ultraviolet light having such a wavelength, an aluminum gallium nitride (AlGaN)-based semiconductor material having a band gap of about 3.4 eV or larger is used. The embodiment particularly shows a case of emitting deep ultraviolet light having a central wavelength λ of about 240 nm-320 nm.

In this specification, the term “AlGaN-based semiconductor material” refers to a semiconductor material containing at least aluminum nitride (AlN) and gallium nitride (GaN) and shall encompass a semiconductor material containing other materials such as indium nitride (InN). Therefore, “AlGaN-based semiconductor materials” as recited in this specification can be represented by a composition In_{1-x-y}AlₓGa_{y}N (0<x+y≤1, 0<x<1, 0<y<1). The AlGaN-based semiconductor material shall encompass AlGaN or InAlGaN. The “AlGaN-based semiconductor material” in this specification has a molar fraction of AlN and a molar fraction of GaN of 1% or higher, and, preferably, 5% or higher, 10% or higher, or 20% or higher.

Those materials that do not contain AlN may be distinguished by referring to them as “GaN-based semiconductor materials”. “GaN-based semiconductor materials” include GaN or InGaN. Similarly, those materials that do not contain GaN may be distinguished by referring to them as “AlN-based semiconductor materials”. “AlN-based semiconductor materials” encompass AlN and InAlN.

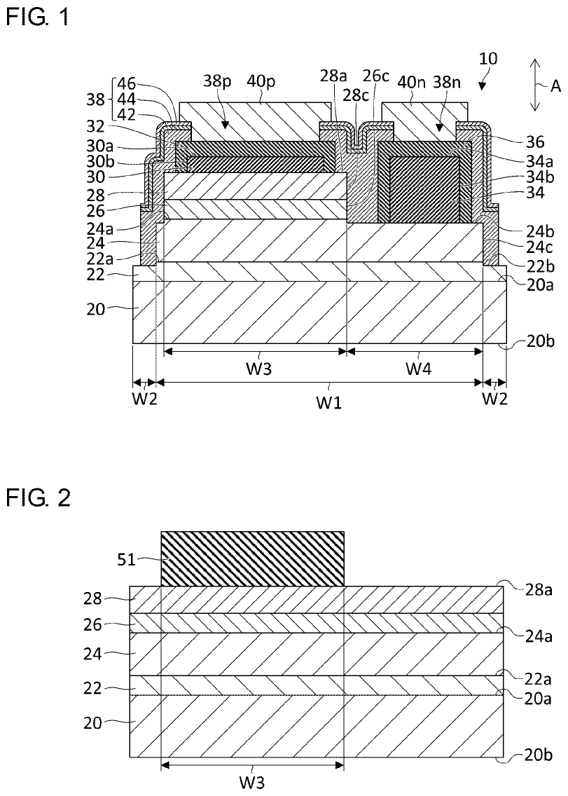

FIG. 1 is a cross-sectional view schematically showing a configuration of a semiconductor light-emitting element 10 according to the embodiment. The semiconductor light-emitting element 10 includes a substrate 20, a base layer 22, an n-type semiconductor layer 24, an active layer 26, a p-type semiconductor layer 28, a p-side contact electrode 30, a p-side current diffusion layer 32, an n-side contact electrode 34, an n-side current diffusion layer 36, a protective layer 38, a p-side pad electrode 40p, and an n-side pad electrode 40n.

Referring to FIG. 1, the direction indicated by the arrow A may be referred to as “vertical direction” or “direction of thickness”. In a view of the substrate 20, the direction away from the substrate 20 may be referred to as upward, and the direction toward the substrate 20 may be referred to as downward.

The substrate 20 includes a first principal surface 20a and a second principal surface 20b opposite to the first principal surface 20a. The first principal surface 20a is a crystal growth surface for growing the layers from the base layer 22 to the p-type semiconductor layer 28. The substrate 20 is made of a material having translucency for the deep ultraviolet light emitted by the semiconductor light-emitting element 10 and is made of, for example, a sapphire (Al₂O₃). A fine concave-convex pattern (not shown) having a submicron (1 μm or less) depth and pitch is formed on the first principal surface 20a. The substrate 20 like this is also called a patterned sapphire substrate (PSS). The second principal surface 20b is a light extraction substrate for extracting the deep ultraviolet light emitted by the active layer 26 outside. The substrate 20 may be made of AlN or made of AlGaN. The first principal surface 20a of the substrate 20 may be configured as a flat surface that is not patterned.

The base layer 22 is provided on the first principal surface 20a of the substrate 20. The base layer 22 is a foundation layer (template layer) to form the n-type semiconductor layer 24. For example, the base layer 22 is an undoped AlN layer and is, specifically, an AlN (HT-AlN; High Temperature AlN) layer grown at a high temperature. The base layer 22 may include an undoped AlGaN layer formed on the AlN layer. The base layer 22 may be comprised only of an undoped AlGaN layer when the substrate 20 is an AlN substrate or an AlGaN substrate. In other words, the base layer 22 includes at least one of an undoped AlN layer or an undoped AlGaN layer.

The base layer 22 includes a first upper surface 22a and second upper surface 22b. The first upper surface 22a is where the n-type semiconductor layer 24 is formed, and the second upper surface 22b is where the n-type semiconductor layer 24 is not formed. The region where the first upper surface 22a is located is defined as “first region W1”, and the region where the second upper surface 22b is located is defined as “second region W2”. The second region W2 is defined to have a shape of a framework along the outer circumference of the semiconductor light-emitting element 10. The first region W1 is defined inside the second region W2.

The n-type semiconductor layer 24 is provided on the first upper surface 22a of the base layer 22. The n-type semiconductor layer 24 is an n-type AlGaN-based semiconductor material layer. For example, the n-type semiconductor layer 24 is an AlGaN layer doped with Si as an n-type impurity. The composition ratio of the n-type semiconductor layer 24 is selected to transmit the deep ultraviolet light emitted by the active layer 26. For example, the n-type semiconductor layer 24 is formed such that the molar fraction of AlN is 25% or higher, and, preferably, 40% or higher or 50% or higher. The n-type semiconductor layer 24 has a band gap larger than the wavelength of the deep ultraviolet light emitted by the active layer 26. For example, the n-type semiconductor layer 24 is formed to have a band gap of 4.3 eV or larger. It is preferable to form the n-type semiconductor layer 24 such that the molar fraction of AlN is 80% or lower, i.e., the band gap is 5.5 eV or smaller. It is more desired to form the n-type semiconductor layer 24 such that the molar fraction of AlN is 70% or lower (i.e., the band gap is 5.2 eV or smaller). The n-type semiconductor layer 24 has a thickness of about 1 μm-3 μm. For example, the n-type semiconductor layer 24 has a thickness of about 2 μm.

The n-type semiconductor layer 24 is formed such that the concentration of Si as the impurity is equal to or more than 1×10¹⁸/cm³ and equal to or less than 5×10¹⁹/cm³. It is preferred to form the n-type semiconductor layer 24 such that the Si concentration is equal to or more than 5×10¹⁸/cm³ and equal to or less than 3×10¹⁹/cm³ and, more preferably, equal to or more than 7×10¹⁸/cm³ and equal to or less than 2×10¹⁹/cm³. In one example, the Si concentration in the n-type semiconductor layer 24 is around 1×10¹⁹/cm³ and is in a range equal to or more than 8×10¹⁸/cm³ and equal to or less than 1.5×10¹⁹/cm³.

The n-type semiconductor layer 24 includes a first upper surface 24a and a second upper surface 24b. The first upper surface 24a is where the active layer 26 is formed, and the second upper surface 24b is where the active layer 26 is not formed. The region where the first upper surface 24a is located is defined as “third region W3”, and the region where the second upper surface 24b is located is defined as “fourth region W4”. The fourth region W4 is adjacent to the third region W3.

The active layer 26 is provided on the first upper surface 24a of the n-type semiconductor layer 24. The active layer 26 is made of an AlGaN-based semiconductor material and has a double heterojunction structure by being sandwiched between the n-type semiconductor layer 24 and the p-type semiconductor layer 28. To output deep ultraviolet light having a wavelength of 355 nm or shorter, the active layer 26 is formed to have a band gap of 3.4 eV or larger. For example, the AlN composition ratio of the active layer 26 is selected so as to output deep ultraviolet light having a wavelength of 320 nm or shorter.

For example, the active layer 26 has a monolayer or multilayer quantum well structure and is comprised of stack of a barrier layer made of an undoped AlGaN-based semiconductor material and a well layer made of an undoped AlGaN-based semiconductor material. The active layer 26 includes, for example, a first barrier layer directly in contact with the n-type semiconductor layer 24 and a first well layer provided on the first barrier layer. One or more pairs of the barrier layer and the well layer may be additionally provided between the first well layer and the p-type semiconductor layer 28. The barrier layer and the well layer have a thickness of about 1 nm-20 nm, and have a thickness of, for example, about 2 nm-10 nm.

The active layer 26 may further include an electron blocking layer directly in contact with the p-type semiconductor layer 28. The electron blocking layer is an undoped AlGaN-based semiconductor material layer and is formed such that, for example, the molar fraction of AlN is 40% or higher, and, preferably, 50% or higher. The electron blocking layer may be formed such that the molar fraction of AlN is 80% or higher or may be made of an AlN-based semiconductor material that does not substantially contain GaN. The electron blocking layer has a thickness of about 1 nm-10 nm. For example, the electron blocking layer has a thickness of about 2 nm-5 nm.

The p-type semiconductor layer 28 is formed on the active layer 26. The p-type semiconductor layer 28 is a p-type AlGaN-based semiconductor material layer or a p-type GaN-based semiconductor material layer. For example, the p-type semiconductor layer 28 is an AlGaN layer or a GaN layer doped with magnesium (Mg) as a p-type impurity. For example, the p-type semiconductor layer 28 has a thickness of about 20 nm-400 nm.

The p-type semiconductor layer 28 may have a stack structure in which a plurality of layers are stacked. The p-type semiconductor layer 28 may include, for example, a p-type clad layer and a p-type contact layer. The p-type clad layer is a p-type AlGaN layer having a relatively high AlN ratio as compared with the p-type contact layer and is provided to be directly in contact with the active layer 26. The p-type contact layer is a p-type AlGaN layer or a p-type GaN layer having a relatively low AlN ratio as compared with the p-type clad layer. The p-type contact layer is provided on the p-type clad layer and is provided to be directly in contact with the p-side contact electrode 30. The p-type clad layer may include a p-type first clad layer and a p-type second clad layer.

The composition ratio of the p-type first clad layer is selected to transmit the deep ultraviolet light emitted by the active layer 26. For example, the p-type first clad layer is formed such that the molar fraction of AlN is 25% or higher, and, preferably, 40% or higher or 50% or higher. The AlN ratio of the p-type first clad layer is, for example, similar to the AlN ratio of the n-type semiconductor layer 24 or larger than the AlN ratio of the n-type semiconductor layer 24. The AlN ratio of the p-type clad layer may be 70% or higher, or 80% or higher. The p-type first clad layer has a thickness of about 10 nm-100 nm. For example, the p-type first clad layer has a thickness of about 15 nm-70 nm.

The p-type second clad layer is provided on the p-type first clad layer. The p-type second clad layer is a p-type AlGaN layer having a medium AlN ratio and has an AlN ratio lower than the AlN ratio of the p-type first clad layer and higher than the AlN ratio of the p-type contact layer. For example, the p-type second clad layer is formed such that the molar fraction of AlN is 25% or higher, and, preferably, 40% or higher or 50% or higher. The AlN ratio of the p-type second clad layer is configured to be, for example, about ±10% of the AlN ratio of the n-type semiconductor layer 24. The p-type second clad layer has a thickness of about 5 nm-250 nm and has a thickness of, for example, about 10 nm-150 nm. The p-type second clad layer may not be provided. The p-type clad layer may be comprised only of the p-type first clad layer.

The p-type contact layer is a p-type AlGaN layer or a p-type GaN layer having a relatively low AlN ratio. The p-type contact layer is formed such that the AlN ratio is 20% or lower in order to obtain proper ohmic contact with the p-side contact electrode 30. Preferably, the p-type contact layer is formed such that the AlN ratio is 10% or lower, 5% or lower, or 0%. In other words, the p-type contact layer may be made of a p-type GaN-based semiconductor material that does not substantially contain AlN. As a result, the p-type contact layer could absorb the deep ultraviolet light emitted by the active layer 26. It is preferred to form the p-type contact layer to be thin to reduce the quantity of absorption of the deep ultraviolet light emitted by the active layer 26. The p-type contact layer has a thickness of about 5 nm-30 nm and has a thickness of, for example, about 10 nm-20 nm.

The p-side contact electrode 30 is provided on the p-type semiconductor layer 28. The p-side contact electrode 30 can be in ohmic contact with the p-type semiconductor layer 28 (more specifically, the p-type contact layer) and is made of a material having a high reflectivity for the deep ultraviolet light emitted by the active layer 26. The p-side contact electrode 30 includes a platinum group metal such as rhodium (Rh). It is preferred that the p-side contact electrode 30 does not contain gold (Au), which could cause reduction in the ultraviolet reflectivity. The thickness of the p-side contact electrode 30 is about 50 nm-200 nm.

The p-side contact electrode 30 may have a stack structure of an Rh layer and an Al layer. In this case, the Rh layer is provided to be directly in contact with the upper surface of the p-type semiconductor layer 28. The Al layer is provided on the Rh layer. It is preferred to configure the thickness of the Rh layer to be 10 nm or smaller and, more preferably, 5 nm or smaller. It is preferred to configure the thickness of the Al layer to be 20 nm or larger and, more preferably, 100 nm or larger. By configuring the thickness of the Rh layer to be 10 nm or smaller and the thickness of the Al layer to be 20 nm or larger, the contact resistance of the p-side contact electrode 30 of 1×10⁻² Ω·cm² or smaller (e.g., 1×10⁻⁴ Ω·cm² or smaller) and the reflectivity of 70% or higher (e.g., about 71%-81%) for ultraviolet light having a wavelength of 280 nm can be obtained.

The p-side contact electrode 30 may further include a Ti layer provided on the Rh layer or the Al layer and a TiN layer provided on the Ti layer. The Ti layer is provided to prevent the Rh layer or the Al layer from being oxidized and corroded. The thickness of the Ti layer is 10 nm or larger and is, for example, about 25 nm-50 nm. The TiN layer is made of titanium nitride (TiN) having conductivity. The conductivity of TiN having conductivity is 1×10⁻⁵ Ω·m or lower, and is, for example, about 4×10⁻⁷ Ω·m. The thickness of the Ti layer is 5 nm or larger and is, for example, about 10 nm-50 nm. The p-side contact electrode 30 may not include at least one of the Ti layer or the TiN layer.

The p-side current diffusion layer 32 is provided on the p-side contact electrode 30. The p-side current diffusion layer 32 is provided to cover an upper surface 30a and a side surface 30b of the p-side contact electrode 30. It is preferred that the p-side current diffusion layer 32 has a certain thickness in order to diffuse the current injected from the p-side pad electrode 40p in the lateral direction (horizontal direction). The thickness of the p-side current diffusion layer 32 is equal to or more than 100 nm and equal to or less than 500 nm and is, for example, about 200 nm-300 nm.

The p-side current diffusion layer 32 has a stack structure in which a first TiN layer, a metal layer, and a second TiN layer are sequentially stacked. The first TiN layer and the second TiN layer of the p-side current diffusion layer 32 are made of titanium nitride having conductivity. The thickness of each of the first TiN layer and the second TiN layer of the p-side current diffusion layer 32 is 10 nm or larger and is, for example, about 50 nm-200 nm.

The metal layer of the p-side current diffusion layer 32 is comprised of a single metal layer or a plurality of metal layers. The metal layer of the p-side current diffusion layer 32 is made of a metal material such as titanium (Ti), chromium (Cr), nickel (Ni), aluminum (Al), platinum (Pt), palladium (Pd), or rhodium (Rh). The metal layer of the p-side current diffusion layer 32 may have a structure in which a plurality of metal layers made of different materials are stacked. The metal layer of the p-side current diffusion layer 32 may have a structure in which a first metal layer made of a first metal material and a second metal layer made of a second metal material are stacked. The metal layer of the p-side current diffusion layer 32 may have a structure in which a plurality of first metal layers and a plurality of second metal layers are alternately stacked. The metal layer of the p-side current diffusion layer 32 may further include a third metal layer made of a third metal material. The thickness of the metal layer of the p-side current diffusion layer 32 is larger than the thickness of each of the first TiN layer and the second TiN layer. The thickness of the metal layer of the p-side current diffusion layer 32 is 50 nm or larger, and is, for example, about 100 nm-300 nm.

The n-side contact electrode 34 is provided on the second upper surface 24b of the n-type semiconductor layer 24. The n-side contact electrode 34 is provided in the fourth region W4 different from the third region W3 in which the active layer 26 is provided. The n-side contact electrode 34 is made of a material that can be in ohmic contact with the n-type semiconductor layer 24 and has a high reflectivity for the deep ultraviolet light emitted by the active layer 26.

The n-side contact electrode 34 includes a Ti layer directly in contact with the n-type semiconductor layer 24 and an Al layer directly in contact with the Ti layer. The thickness of the Ti layer is about 1 nm-10 nm and, preferably, 5 nm or smaller and, more preferably, 1 nm-2 nm. By configuring the Ti layer to have a small thickness, the ultraviolet reflectivity of the n-side contact electrode 34 as viewed from the n-type semiconductor layer 24 can be increased. It is preferred to configure the thickness of the Al layer to be 200 nm or larger. The thickness of the Al layer is, for example, about 300 nm-1000 nm. By configuring the Al layer to have a large thickness, the ultraviolet reflectivity of the n-side contact electrode 34 can be increased.

The n-side contact electrode 34 may further include a TiN layer provided on the Al layer and a TiN layer provided on the Ti layer. The Ti layer is provided to prevent the Al layer from being oxidized. The thickness of the Ti layer is 10 nm or larger and is, for example, about 25 nm-50 nm. The TiN layer is made of titanium nitride (TiN) having conductivity. The thickness of the TiN layer is 5 nm or larger and is, for example, about 10 nm-50 nm. The n-side contact electrode 34 may not include at least one of the Ti layer or the TiN layer.

The n-side current diffusion layer 36 is provided on the n-side contact electrode 34. The n-side current diffusion layer 36 is provided to cover an upper surface 34a and a side surface 34b of the n-side contact electrode 34. It is preferred that the n-side current diffusion layer 36 has a certain thickness in order to diffuse the current injected from the n-side pad electrode 40n in the lateral direction (horizontal direction). The thickness of the n-side current diffusion layer 36 is equal to or more than 100 nm and equal to or less than 500 nm and is, for example, about 200 nm-300 nm.

Like the p-side current diffusion layer 32, the n-side current diffusion layer 36 has a stack structure in which a first TiN layer, a metal layer, and a second TiN layer are sequentially stacked. The first TiN layer and the second TiN layer of the n-side current diffusion layer 36 are made of titanium nitride having conductivity. The thickness of each of the first TiN layer and the second TiN layer of the n-side current diffusion layer 36 is 10 nm or larger and is, for example, about 50 nm-200 nm.

The metal layer of the n-side current diffusion layer 36 is comprised of a single metal layer or a plurality of metal layers. As in the p-side current diffusion layer 32, the metal layer of the n-side current diffusion layer 36 is made of a metal material such as titanium (Ti), chromium (Cr), nickel (Ni), aluminum (Al), platinum (Pt), palladium (Pd), or rhodium (Rh). The metal layer of the n-side current diffusion layer 36 may have a structure in which a plurality of metal layers made of different materials are stacked. The metal layer of the n-side current diffusion layer 36 may have a structure in which a first metal layer made of a first metal material and a second metal layer made of a second metal material are stacked. The metal layer of the n-side current diffusion layer 36 may have a structure in which a plurality of first metal layers and a plurality of second metal layers are alternately stacked. The metal layer of the n-side current diffusion layer 36 may further include a third metal layer made of a third metal material. The thickness of the metal layer of the n-side current diffusion layer 36 is larger than the thickness of each of the first TiN layer and the second TiN layer. The thickness of the metal layer of the n-side current diffusion layer 36 is 50 nm or larger, and is, for example, about 100 nm-300 nm.

The protective layer 38 includes a p-side pad opening 38p and an n-side pad opening 38n and is provided to cover the entirety of the upper surface of the semiconductor light-emitting element 10 in a portion different from the p-side pad opening 38p and the n-side pad opening 38n. The p-side pad opening 38p is provided on the p-side contact electrode 30 and the p-side current diffusion layer 32. The n-side pad opening 38n is provided on the n-side contact electrode 34 and the n-side current diffusion layer 36.

The protective layer 38 covers a side surface 24c of the n-type semiconductor layer 24, a side surface 26c of the active layer 26, and a side surface 28c of the p-type semiconductor layer 28. The protective layer 38 covers the p-side contact electrode 30 and the p-side current diffusion layer 32 in a portion different from the p-side pad opening 38p. The protective layer 38 covers an upper surface 28a of the p-type semiconductor layer 28 in a portion different from the p-side contact electrode 30 and the p-side current diffusion layer 32. The protective layer 38 covers the n-side contact electrode 34 and the n-side current diffusion layer 36 in a portion different from the n-side pad opening 38n. The protective layer 38 covers the second upper surface 24b of the n-type semiconductor layer 24 in a portion different from the n-side contact electrode 34 and the n-side current diffusion layer 36. The protective layer 38 is in contact with the second upper surface 22b of the base layer 22.

The protective layer 38 includes a first dielectric layer 42, a second dielectric layer 44, and a third dielectric layer 46. Each of the first dielectric layer 42, the second dielectric layer 44, and the third dielectric layer 46 is made of a material that does not substantially absorb the deep ultraviolet light emitted by the active layer 26 and is made of a material having a transmittance for the wavelength of the deep ultraviolet light emitted by the active layer 26 of 80% or higher. Such a material is exemplified by an oxide material such as silicon oxide (SiO₂), aluminum oxide (Al₂O₃), hafnium oxide (HfO₂).

The first dielectric layer 42 is in direct contact with the n-type semiconductor layer 24, the active layer 26, the p-type semiconductor layer 28, the p-side current diffusion layer 32, and the n-side current diffusion layer 36. The first dielectric layer 42 is made of a first oxide material and is made of SiO₂, Al₂O₃, or HfO₂. The first dielectric layer 42 is preferably made of SiO₂. The thickness of the first dielectric layer 42 is equal to or more than 300 nm and equal to or less than 1500 nm and is, for example, about 600 nm-1000 nm. The thickness of the first dielectric layer 42 is larger than the thickness of the p-side contact electrode 30 or the thickness of the n-side contact electrode 34. The first dielectric layer 42 can be formed by plasma enhanced chemical vapor deposition (PECVD). By using the PECVD method, a dielectric layer having a large thickness can be formed easily.

The second dielectric layer 44 is provided on the first dielectric layer 42 and is provided to cover the entirety of the first dielectric layer 42. The second dielectric layer 44 is made of a second oxide material different from the first oxide material of the first dielectric layer 42 and is made of SiO₂, Al₂O₃, or HfO₂. The second dielectric layer 44 is preferably made of Al₂O₃. By configuring the material of the second dielectric layer 44 to be different from the material of the first dielectric layer 42, pin holes that could be produced in the first dielectric layer 42 can be blocked to increase the quality of sealing. The thickness of the second dielectric layer 44 is equal to or more than 10 nm and equal to or less than 100 nm and is, for example, about 20 nm-50 nm. Therefore, the thickness of the second dielectric layer 44 is smaller than the thickness of the first dielectric layer 42 and is equal to 10% of the thickness of the first dielectric layer 42 or smaller or 5% of the thickness of the first dielectric layer 42 or smaller. The second dielectric layer 44 can be formed by the atomic layer deposition (ALD) method. By using the ALD method, a tight dielectric film having a high film density can be formed.

The third dielectric layer 46 is provided on the second dielectric layer 44 and is provided to cover the entirety of the second dielectric layer 44. The third dielectric layer 46 is made of a third oxide material different from the second oxide material and is preferably made of SiO₂. By configuring the material of the third dielectric layer 46 to be different from the material of the second dielectric layer 44, pin holes that could be produced in the second dielectric layer 44 can be blocked to increase the sealing performance. The thickness of the third dielectric layer 46 is equal to or more than 10 nm and equal to or less than 100 nm and is, for example, about 20 nm-50 nm. Therefore, the thickness of the third dielectric layer 46 is similar to the thickness of the second dielectric layer 44 and is smaller than the thickness of the first dielectric layer 42. The third dielectric layer 46 can be formed by the ALD method. By using the ALD method to form the SiO₂ film, the third dielectric layer 46 having an excellent moisture resistance can be formed.

In the case the first dielectric layer 42 and the third dielectric layer 46 are made of SiO₂, the carbon concentration of the first dielectric layer 42 is smaller than the carbon concentration of the third dielectric layer 46. The carbon concentration of the first dielectric layer 42 is, for example, equal to or more than 4×10¹⁷ cm⁻³ and equal to or less than 2×10¹⁸ cm⁻³. The first dielectric layer 42 is made of SiO₂ that does not substantially contain carbon. For example, the first dielectric layer 42 can be formed by using a silicon compound such as silane (SiH₄) that does not contain carbon and an oxygen compound such as oxygen (O₂), water (H₂O), and nitride oxide (NₓO_{y}) that does not contain carbon. By configuring the carbon concentration of the first dielectric layer 42 to be small, the film quality and ultraviolet transmittance of the first dielectric layer 42 can be improved. Meanwhile, the carbon concentration of the third dielectric layer 46 is, for example, equal to or more than 5×10¹⁸ cm⁻³ and equal to or less than 3×10¹⁹ cm⁻³. From the perspective of facilitating film formation according to the ALD method, it is preferred to form the third dielectric layer 46 by using organic silicon compounds such as tris(dimethylamino)silane (3DMAS), bis(diethylamino)silane (BDEAS), and bis(tertiay-butylamino)silane (BTBAS) that contain carbon. As a result, the third dielectric layer 46 will be made of SiO₂ that contains carbon, which could reduce the film quality and ultraviolet transmittance as compared to the first dielectric layer 42. However, the carbon concentration of the third dielectric layer 46 is so low that the adverse impact from containing carbon is small, and the transmittance of the third dielectric layer 46 for the deep ultraviolet light emitted by the active layer 26 is ensured to be 80% or higher.

In the case the first dielectric layer 42 and the third dielectric layer 46 are made of SiO₂, the film density of the third dielectric layer 46 may be equal to the film density of the first dielectric layer 42. The film density of the third dielectric layer 46 may be larger than the film density of the first dielectric layer 42 or smaller than the film density of the first dielectric layer 42. By configuring the film density of one of the first dielectric layer 42 and the third dielectric layer 46 to be larger than the film density of the other, the moisture resistance of the protective layer 38 can be improved.

The p-side pad electrode 40p and the n-side pad electrode 40n are portions bonded when the semiconductor light-emitting element 10 is mounted on a package substrate or the like. The p-side pad electrode 40p is provided on the protective layer 38 and is in contact with the p-side current diffusion layer 32 in the p-side pad opening 38p. The p-side pad electrode 40p is electrically connected to the p-side contact electrode 30 via the p-side current diffusion layer 32. The n-side pad electrode 40n is provided on the protective layer 38 and is in contact with the n-side current diffusion layer 36 in the n-side pad opening 38n. The n-side pad electrode 40n is electrically connected to the n-side contact electrode 34 via the n-side current diffusion layer 36.

From the perspective of providing resistance to corrosion, the p-side pad electrode 40p and the n-side pad electrode 40n are configured to contain Au. For example, the p-side pad electrode 40p and the n-side pad electrode 40n are comprised of a Ni/Au, Ti/Au, or Ti/Pt/Au stack structure. In the case the p-side pad electrode 40p and the n-side pad electrode 40n are bonded by gold-tin (AuSn), an AuSn layer embodying a metal joining member may be included in the p-side pad electrode 40p and the n-side pad electrode 40n. The thickness of the p-side pad electrode 40p and the n-side pad electrode 40n is 100 nm or larger and is, for example, about 200 nm-1000 nm.

A description will now be given of a method of manufacturing the semiconductor light-emitting element 10. FIGS. 2-10 schematically show steps of manufacturing the semiconductor light-emitting element 10. First, referring to FIG. 2, the base layer 22, the n-type semiconductor layer 24, the active layer 26, and the p-type semiconductor layer 28 are formed on the first principal surface 20a of the substrate 20 sequentially.

The substrate 20 is, for example, a patterned sapphire substrate. The base layer 22 includes, for example, an HT-AlN layer and an undoped AlGaN layer. The n-type semiconductor layer 24, the active layer 26, and the p-type semiconductor layer 28 are semiconductor layers made of an AlGaN-based semiconductor material, an AlN-based semiconductor material, or a GaN-based semiconductor material and can be formed by a well-known epitaxial growth method such as the metal organic vapor phase epitaxy (MOVPE) method and the molecular beam epitaxy (MBE) method.

A first mask 51 is then formed on the upper surface 28a of the p-type semiconductor layer 28. The first mask 51 is provided in the third region W3. The first mask 51 is an etching mask for forming the side surfaces 26c, 28c (also referred to as mesa surfaces) of the active layer 26 and the p-type semiconductor layer 28. The first mask 51 can be formed by using a publicly known photolithographic technology.

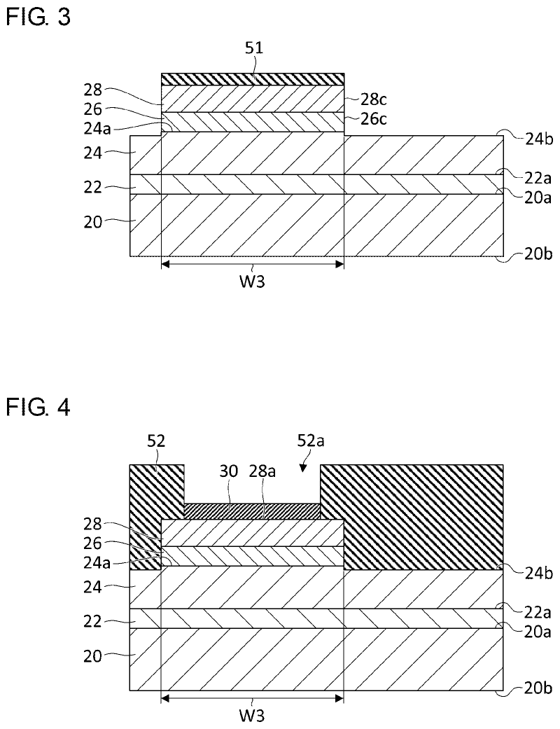

Subsequently, as shown in FIG. 3, the p-type semiconductor layer 28 and the active layer 26 are etched while the first mask 51 is being formed, to expose the n-type semiconductor layer 24 in a region different from the third region W3. This etching step forms the side surfaces 26c, 28c of the active layer 26 and the p-type semiconductor layer 28 and forms the second upper surface 24b of the n-type semiconductor layer 24.

In the etching step of FIG. 3, reactive ion etching using a chlorine-based etching gas can be used, and inductive coupling plasma (ICP) etching can be used. For example, a reactive gas including chlorine (Cl) such as chlorine (Cl₂), boron trichloride (BCl₃), and silicon tetrachloride (SiCl₄) can be used as the etching gas. Dry etching may be performed by combining a reactive gas and an inert gas, or a noble gas such as argon (Ar) may be mixed with the chlorine-based gas. The first mask 51 is removed after the second upper surface 24b of the n-type semiconductor layer 24 is formed.

Subsequently, as shown in FIG. 4, a second mask 52 having an opening 52a is formed on the upper surface 28a of the p-type semiconductor layer 28, and the p-side contact electrode 30 is formed on the upper surface 28a of the p-type semiconductor layer 28 in the opening 52a. The second mask 52 can be formed by using a publicly known photolithographic technology. The p-side contact electrode 30 can be formed by, for example, stacking Rh/Al/Ti/TiN sequentially. The p-side contact electrode 30 can be formed by sputtering.

The second mask 52 is then removed, and the p-side contact electrode 30 is annealed. The p-side contact electrode 30 is annealed at a temperature below the melting point of Al (about 660° C.). For example, the p-side contact electrode 30 is annealed at a temperature equal to or more than 500° C. and equal to or less than 650° C. and, preferably, at a temperature equal to or more than 550° C. and equal to or less than 625° C. Annealing the p-side contact electrode 30 ensures that the contact resistance of the p-side contact electrode 30 is 1×10⁻² Ω·cm² or smaller (e.g., 1×10⁻⁴ Ω·cm² or smaller), and the reflectivity for ultraviolet light having a wavelength of 280 nm is 70% or higher (e.g., about 71%-81%).

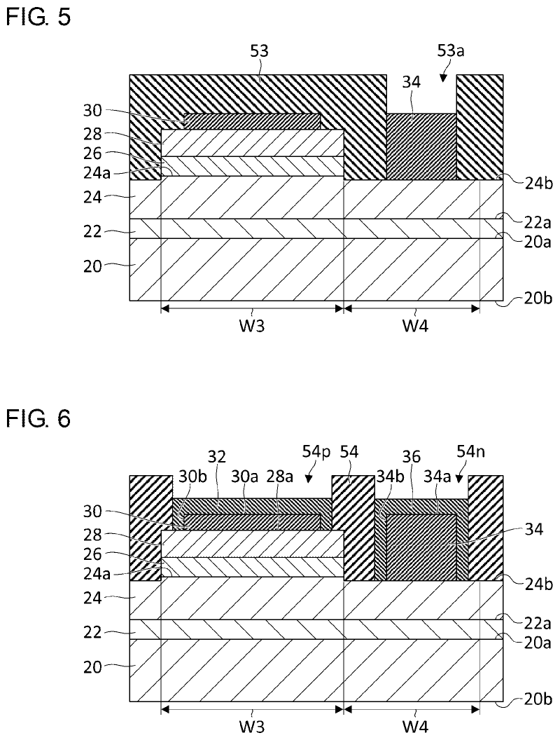

Subsequently, as shown in FIG. 5, a third mask 53 having an opening 53a is formed on the second upper surface 24b of the n-type semiconductor layer 24, and the n-side contact electrode 34 is formed on the second upper surface 24b of the n-type semiconductor layer 24 in the opening 53a. The third mask 53 can be formed by using a publicly known photolithographic technology. The n-side contact electrode 34 can be formed by, for example, stacking Ti/Al/Ti/TiN sequentially. The n-side contact electrode 34 can be formed by sputtering.

The third mask 53 is then removed, and the n-side contact electrode 34 is annealed. The n-side contact electrode 34 is annealed at a temperature below the melting point of Al (about 660° C.). For example, the n-side contact electrode 34 is annealed at a temperature equal to or more than 500° C. and equal to or less than 650° C. and, preferably, at a temperature equal to or more than 550° C. and equal to or less than 625° C. Annealing ensures that the contact resistance of the n-side contact electrode 34 is 1×10⁻² Ω·cm² or smaller. Further, the annealing temperature of equal to or more than 560° C. and equal to or less than 650° C. increases the post-annealing flatness of the n-side contact electrode 34 and produces an ultraviolet reflectivity of 80% or higher (e.g., about 90%).

Subsequently, as shown in FIG. 6, a fourth mask 54 having a p-side opening 54p in a region larger than the p-side contact electrode 30 on the upper surface 28a of the p-type semiconductor layer 28 and an n-side opening 54n in a region larger than the n-side contact electrode 34 on the second upper surface 24b of the n-type semiconductor layer 24 is formed. The fourth mask 54 can be formed by using a publicly known photolithographic technology. Subsequently, the p-side current diffusion layer 32 that covers the upper surface 30a and the side surface 30b of the p-side contact electrode 30 in the p-side opening 54p is formed, and the n-side current diffusion layer 36 that covers the upper surface 34a and the side surface 34b of the n-side contact electrode 34 in the n-side opening 54n is formed. The p-side current diffusion layer 32 and the n-side current diffusion layer 36 can be formed by stacking a TiN layer, a metal layer, and TiN layer sequentially. The p-side current diffusion layer 32 and the n-side current diffusion layer 36 can be formed by sputtering. After the p-side current diffusion layer 32 and the n-side current diffusion layer 36 are formed, the fourth mask 54 is removed.

The p-side current diffusion layer 32 and the n-side current diffusion layer 36 may not be formed concurrently, and the p-side current diffusion layer 32 and the n-side current diffusion layer 36 may be formed separately. For example, a mask having only the p-side opening 54p may be used to form the p-side current diffusion layer 32, and then a mask having only the n-side opening 54n may be used to form the n-side current diffusion layer 36. In this case, the sequence of forming the p-side current diffusion layer 32 and the n-side current diffusion layer 36 is not limited to a particular pattern, and the p-side current diffusion layer 32 may be formed after the n-side current diffusion layer 36 is formed.

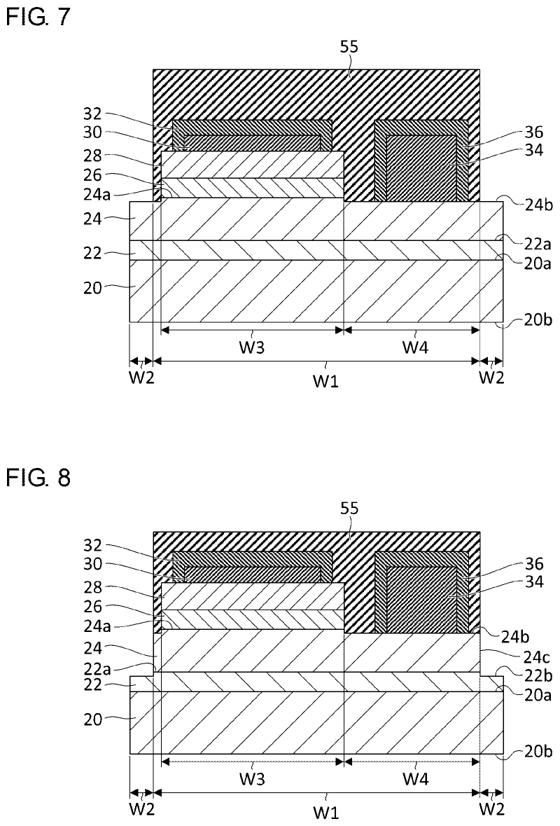

Subsequently, as shown in FIG. 7, a fifth mask 55 is formed to cover the active layer 26, the p-type semiconductor layer 28, the p-side current diffusion layer 32, and the n-side current diffusion layer 36. The fifth mask 55 is provided in the first region W1 and is not provided in the second region W2. The fifth mask 55 is an etching mask for forming the second upper surface 22b of the base layer 22 and the side surface 24c of the n-type semiconductor layer 24. The fifth mask 55 can be formed by using a publicly known photolithographic technology.

Subsequently, as shown in FIG. 8, the n-type semiconductor layer 24 is etched while the fifth mask 55 is being formed, to expose the base layer 22 in the second region W2. This etching step forms the side surface 24c of the n-type semiconductor layer 24 and forms the second upper surface 22b of the base layer 22. The fifth mask 55 is then removed.

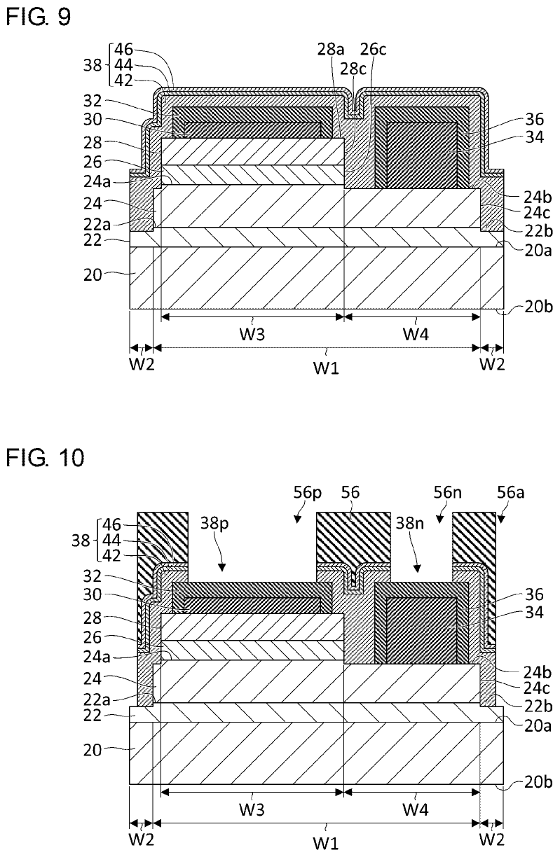

Subsequently, as shown in FIG. 9, the protective layer 38 is formed to cover the entirety of the upper surface of the element structure. First, the first dielectric layer 42 made of the first oxide material is formed. The first dielectric layer 42 can be made of SiO₂ and can be formed by using the PECVD method. The first dielectric layer 42 is formed by using a silicon compound and an oxide compound that do not contain carbon and can be made of SiO₂ that does not substantially contain carbon. The first dielectric layer 42 is provided to cover the second upper surface 24b and the side surface 24c of the n-type semiconductor layer 24, the side surface 26c of the active layer 26, the upper surface 28a and the side surface 28c of the p-type semiconductor layer 28, the p-side current diffusion layer 32, and the n-side current diffusion layer 36. The first dielectric layer 42 is also provided on the second upper surface 22b of the base layer 22 in the second region W2.

Subsequently, the second dielectric layer 44 made of the second oxide material is formed on the first dielectric layer 42. The second dielectric layer 44 is formed to cover the the entirety of the upper surface of the first dielectric layer 42. The second dielectric layer 44 can be made of Al₂O₃ and can be formed by using the ALD method. Subsequently, the third dielectric layer 46 made of SiO₂ is formed on the second dielectric layer 44. The third dielectric layer 46 is formed to cover the entirety of the upper surface of the second dielectric layer 44. The third dielectric layer 46 can be formed by using the ALD method. The third dielectric layer 46 is formed by using an organic silicon compound containing carbon and can be made of SiO₂ containing a slight amount of carbon.

Subsequently, as shown in FIG. 10, a sixth mask 56 having an outer circumferential opening 56a, a p-side opening 56p, and an n-side opening 56n is formed on the protective layer 38. The outer circumferential opening 56a is located in the second region W2. The p-side opening 56p is located above the p-side contact electrode 30 and the p-side current diffusion layer 32. The n-side opening 56n is located above the n-side contact electrode 34 and the n-side current diffusion layer 36. The sixth mask 56 can be formed by using a publicly known photolithographic technology. Subsequently, the protective layer 38 is dry-etched in the outer circumferential opening 56a, the p-side opening 56p, and the n-side opening 56n. The protective layer 38 can be dry-etched by using a CF-based etching gas such as hexafluoroethane (C₂F₆). This etching step forms the p-side pad opening 38p and the n-side pad opening 38n extending through the first dielectric layer 42, the second dielectric layer 44, and the third dielectric layer 46. Further, a portion of the second upper surface 22b of the base layer 22 is exposed in the second region W2. The protective layer 38 may be prevented from being formed in a portion of the second upper surface 22b of the base layer 22 by forming the protective layer 38 while a mask is provided in a portion of the second region W2 in the step of FIG. 9. In this case, the sixth mask 56 used in the step of FIG. 10 has the p-side opening 56p and the n-side opening 56n and does not have the outer circumferential opening 56a.

In the dry-etching step of FIG. 10, the second TiN layer of the p-side current diffusion layer 32 and the n-side current diffusion layer 36 functions as an etching stop layer. TiN is not so reactive to a fluorine-based etching gas for removing the protective layer 38 so that by-products from etching are not easily produced. Therefore, a damage to the p-side contact electrode 30, the p-side current diffusion layer 32, the n-side contact electrode 34, and the n-side current diffusion layer 36 can be prevented in the step of etching the protective layer 38. After the p-side pad opening 38p and the n-side pad opening 38n are formed, the sixth mask 56 is removed.

Subsequently, the p-side pad electrode 40p is formed to block the p-side pad opening 38p, and the n-side pad electrode 40n is formed to block the n-side pad opening 38n. The p-side pad electrode 40p and the n-side pad electrode 40n can be formed by, for example, building an Ni layer or a Ti layer and stacking an Au layer thereon. Another metal layer may be provided on the Au layer. For example, a stack structure of an Sn layer, an AuSn layer, or a Sn/Au may be formed. The p-side pad electrode 40p and the n-side pad electrode 40n may be formed by using the sixth mask 56 or may be formed by using a resist mask separate from the sixth mask 56. After the p-side pad electrode 40p and the n-side pad electrode 40n are formed, the sixth mask 56 or the separate resist mask is removed.

The semiconductor light-emitting element 10 of FIG. 1 is completed through the steps described above.

According to the embodiment, all of the first dielectric layer 42, the second dielectric layer 44, and the third dielectric layer 46 forming the protective layer 38 are made of a material having a transmittance for the wavelength of the deep ultraviolet light emitted by the active layer 26 of 80% or higher. As a result, absorption of deep ultraviolet light by the protective layer 38 can be prevented, and the light extraction efficiency of the semiconductor light-emitting element 10 can be improved.

According to the embodiment, pin holes that could be produced in the first dielectric layer 42 can be blocked by the second dielectric layer 44 by configuring the materials of the first dielectric layer 42 and the second dielectric layer 44 to be different. By configuring the materials of the second dielectric layer 44 and the third dielectric layer 46 to be different, pin holes that could be produced in the second dielectric layer 44 can be blocked by the third dielectric layer 46. Further, the coverage performance of the second dielectric layer 44 and the third dielectric layer 46 can be increased by forming the second dielectric layer 44 and the third dielectric layer 46 by using the ALD method. This increases the quality of sealing by the protective layer 38.

According to the embodiment, the moisture resistance of the protective layer 38 can be increased by configuring the third dielectric layer 46 forming the outermost surface of the protective layer 38 to be made of SiO₂ by using the ALD method. In particular, the moisture resistance of the protective layer 38 can be improved by configuring the third dielectric layer 46 made of SiO₂ to be the outermost surface of the protective layer 38 as compared with the case of configuring the second dielectric layer 44 made of Al₂O₃ or the like to be the outermost surface of the protective layer 38.

According to the embodiment, the impact from the ultraviolet light emitted by the active layer 26 being absorbed by the first dielectric layer 42 can be reduced by configuring the carbon concentration of the first dielectric layer 42 directly in contact with the active layer 26 to be small. This increases the light extraction efficiency of the semiconductor light-emitting element 10.

According to the embodiment, using Rh in the p-side contact electrode 30 increases the ultraviolet reflectivity of the p-side contact electrode 30 and causes the p-side contact electrode 30 to function as a high-performance reflection electrode. Further, the reflectivity of the p-side contact electrode 30 can be configured to be 80% or higher, by using an Rh layer and an Al layer in combination in the p-side contact electrode 30 and configuring the thickness of the Rh layer to be 5 nm or smaller. In this case, the light extraction efficiency can be increased by about 8% as compared with the case of configuring the p-side contact electrode 30 to be comprised solely of an Rh layer.

Described above is an explanation based on an exemplary embodiment. The embodiment is intended to be illustrative only and it will be understood by those skilled in the art that various design changes are possible and various modifications are possible and that such modifications are also within the scope of the present invention.

A description will be given below of some embodiments of the present invention.

The first embodiment of the present invention relates to a semiconductor light-emitting element including: an n-type semiconductor layer made of an n-type AlGaN-based semiconductor material; an active layer provided on a first upper surface of the n-type semiconductor layer and made of an AlGaN-based semiconductor material; a p-type semiconductor layer provided on the active layer; a p-side contact electrode provided on an upper surface of the p-type semiconductor layer and containing Rh; an n-side contact electrode provided on a second upper surface of the n-type semiconductor layer; a protective layer including a p-side pad opening provided on the p-side contact electrode and an n-side pad opening provided on the n-side contact electrode, the protective layer covering side surfaces of the n-type semiconductor layer, the active layer, and the p-type semiconductor layer, covering the p-side contact electrode in a portion different from the p-side pad opening, and covering the n-side contact electrode in a portion different from the n-side pad opening; a p-side pad electrode connected to the p-side contact electrode in the p-side pad opening; and and an n-side pad electrode connected to the n-side contact electrode in the n-side pad opening, wherein the protective layer includes a first dielectric layer made of SiO₂, a second dielectric layer made of an oxide material different from a material of the first dielectric layer and covering the first dielectric layer, and a third dielectric layer made of SiO₂ and covering the second dielectric layer, a carbon concentration of the first dielectric layer is smaller than a carbon concentration of the third dielectric layer, and each of the first dielectric layer, the second dielectric layer, and the third dielectric layer has a transmittance for deep ultraviolet light emitted by the active layer of 80% or higher. According to the first embodiment, pin holes that could be produced in the first dielectric layer can be blocked suitably by the second dielectric layer by configuring the materials of the first dielectric layer and the second dielectric layer forming the protective layer to be different. Further, the moisture resistance of the protective layer can be increased by configuring the third dielectric layer forming the outermost surface of the protective layer to be made of SiO₂. Further, absorption of deep ultraviolet light by the protective layer can be prevented, and the light extraction efficiency of the light-emitting element can be increased, by configuring the carbon concentration of the first dielectric layer to be small and configuring the transmittance of the first dielectric layer, the second dielectric layer, and the third dielectric layer for the wavelength of deep ultraviolet light to be 80% or higher.

The second embodiment of the present invention relates to the semiconductor light-emitting element according to the first embodiment, wherein a thickness of the first dielectric layer is larger than a thickness of the n-side contact electrode and a thickness of the p-side contact electrode. According to the second embodiment, it is possible to seal the contact electrode properly and increase the reliability of the light-emitting element by configuring the thickness of the first dielectric layer to be larger than the thickness of the contact electrode.

The third embodiment of the present invention relates to the semiconductor light-emitting element according to the first embodiment, wherein a thickness of the first dielectric layer is equal to or more than 500 nm and equal to or less than 1000 nm, and a thickness of the second dielectric layer and a thickness of the third dielectric layer are equal to or more than 10 nm and equal to or more than 100 nm. According to the third embodiment, the contact electrode can be properly sealed by configuring the thickness of the first dielectric layer to be equal to or more than 500 nm and equal to or less than 1000 nm. Further, pin holes that could be produced in the first dielectric layer can be blocked by the second dielectric layer, and the moisture resistance can be improved by the third dielectric layer, by configuring the thickness of the second dielectric layer and the third dielectric layer to be equal to or more than 10 nm and equal to or less than 100 nm.

The fourth embodiment of the present invention relates to a method of manufacturing a semiconductor light-emitting element, including: forming an active layer made of an AlGaN-based semiconductor material on a first upper surface of an n-type semiconductor layer made of an n-type AlGaN-based semiconductor material; forming a p-type semiconductor layer on the active layer; removing a portion of the p-type semiconductor layer and a portion of the active layer to expose a second upper surface of the n-type semiconductor layer; forming a p-side contact electrode containing Rh on an upper surface of the p-type semiconductor layer; forming an n-side contact electrode on a second upper surface of the n-type semiconductor layer; forming a first dielectric layer made of a first oxide material, covering side surfaces of the n-type semiconductor layer, the active layer, and the p-type semiconductor layer, and covering the p-side contact electrode and the n-side contact electrode; forming a second dielectric layer made of a second oxide material different from the first oxide material and covering the first dielectric layer, forming a third dielectric layer made of SiO₂ and covering the second dielectric layer by atomic layer deposition; forming a p-side pad opening by removing the first dielectric layer, the second dielectric layer, and the third dielectric layer above the p-side contact electrode; forming an n-side pad opening by removing the first dielectric layer, the second dielectric layer, and the third dielectric layer above the n-side contact electrode; forming a p-side pad electrode connected to the p-side contact electrode in the p-side pad opening; and forming an n-side pad electrode connected to the n-side contact electrode in the n-side pad opening, wherein each of the first dielectric layer, the second dielectric layer, and the third dielectric layer has a transmittance for deep ultraviolet light emitted by the active layer of 80% or higher. According to the fourth embodiment, pin holes that could be produced in the first dielectric layer can be blocked suitably by the second dielectric layer by configuring the materials of the first dielectric layer and the second dielectric layer forming the protective layer to be different. Further, a tight protective layer having a high moisture resistance can be formed by configuring the third dielectric layer forming the outermost surface of the protective layer to be made of SiO₂ and forming the third dielectric layer by the ALD method. Further, absorption of deep ultraviolet light by the protective layer can be prevented, and the light extraction efficiency of the light-emitting element can be increased, by configuring the transmittance of the first dielectric layer, the second dielectric layer, and the third dielectric layer for the wavelength of deep ultraviolet light to be 80% or higher.

The fifth embodiment of the present invention relates to the method of manufacturing a semiconductor light-emitting element according to the fourth embodiment, wherein the first dielectric layer is formed by plasma enhanced chemical vapor deposition, and the second dielectric layer is formed by atomic layer deposition. According to the fifth embodiment, the thickness of the first dielectric layer can be enlarged easily, and the entirety of the upper surface of the element structure can be sealed properly, by forming the first dielectric layer by the PECVD method. A tight protective layer having a high quality of sealing can be formed by forming the second dielectric layer by the ALD method. This increases the reliability of the protective layer.

What is claimed is:

1. A semiconductor light-emitting element comprising:
an n-type semiconductor layer made of an n-type AlGaN-based semiconductor material;
an active layer provided on a first upper surface of the n-type semiconductor layer and made of an AlGaN-based semiconductor material;
a p-type semiconductor layer provided on the active layer;
a p-side contact electrode provided on an upper surface of the p-type semiconductor layer and containing Rh;
an n-side contact electrode provided on a second upper surface of the n-type semiconductor layer;
a protective layer including a p-side pad opening provided on the p-side contact electrode and an n-side pad opening provided on the n-side contact electrode, the protective layer covering side surfaces of the n-type semiconductor layer, the active layer, and the p-type semiconductor layer, covering the p-side contact electrode in a portion different from the p-side pad opening, and covering the n-side contact electrode in a portion different from the n-side pad opening;
a p-side pad electrode connected to the p-side contact electrode in the p-side pad opening; and
an n-side pad electrode connected to the n-side contact electrode in the n-side pad opening, wherein
the protective layer includes a first dielectric layer made of SiO₂, a second dielectric layer made of an oxide material different from a material of the first dielectric layer and covering the first dielectric layer, and a third dielectric layer made of SiO₂ and covering the second dielectric layer,
a carbon concentration of the first dielectric layer is smaller than a carbon concentration of the third dielectric layer, and
each of the first dielectric layer, the second dielectric layer, and the third dielectric layer has a transmittance for deep ultraviolet light emitted by the active layer of 80% or higher.

2. The semiconductor light-emitting element according to claim 1, wherein
a thickness of the first dielectric layer is larger than a thickness of the n-side contact electrode and a thickness of the p-side contact electrode.

3. The semiconductor light-emitting element according to claim 1, wherein
a thickness of the first dielectric layer is equal to or more than 500 nm and equal to or less than 1000 nm, and
a thickness of the second dielectric layer and a thickness of the third dielectric layer are equal to or more than 10 nm and equal to or more than 100 nm.

4. A method of manufacturing a semiconductor light-emitting element, comprising:
forming an active layer made of an AlGaN-based semiconductor material on a first upper surface of an n-type semiconductor layer made of an n-type AlGaN-based semiconductor material;
forming a p-type semiconductor layer on the active layer;
removing a portion of the p-type semiconductor layer and a portion of the active layer to expose a second upper surface of the n-type semiconductor layer;
forming a p-side contact electrode containing Rh on an upper surface of the p-type semiconductor layer;
forming an n-side contact electrode on a second upper surface of the n-type semiconductor layer;
forming a first dielectric layer made of a first oxide material, covering side surfaces of the n-type semiconductor layer, the active layer, and the p-type semiconductor layer, and covering the p-side contact electrode and the n-side contact electrode;
forming a second dielectric layer made of a second oxide material different from the first oxide material and covering the first dielectric layer,
forming a third dielectric layer made of SiO₂ and covering the second dielectric layer by atomic layer deposition;
forming a p-side pad opening by removing the first dielectric layer, the second dielectric layer, and the third dielectric layer above the p-side contact electrode;
forming an n-side pad opening by removing the first dielectric layer, the second dielectric layer, and the third dielectric layer above the n-side contact electrode;
forming a p-side pad electrode connected to the p-side contact electrode in the p-side pad opening; and
forming an n-side pad electrode connected to the n-side contact electrode in the n-side pad opening, wherein
each of the first dielectric layer, the second dielectric layer, and the third dielectric layer has a transmittance for deep ultraviolet light emitted by the active layer of 80% or higher.

5. The method of manufacturing a semiconductor light-emitting element according to claim 4, wherein
the first dielectric layer is formed by plasma enhanced chemical vapor deposition, and the second dielectric layer is formed by atomic layer deposition.
